(19) United States
(12) Patent Application Publication
(10) Pub. No.: US 2025/0190832 A1
(43) Pub. Date: Jun. 12, 2025

(54) METHOD FOR CALIBRATING AND/OR ASSISTING IN THE DESIGN OF A SPIN-QUBIT OR TWO-LEVEL QUANTUM SYSTEM AND QUANTUM COMPONENT

(71) Applicant: C12 quantum Electronics, Paris (FR)

(72) Inventors: Quentin Schaeverbeke, Paris (FR); Matthieu Desjardins, Paris (FR); Louis Godet, Paris (FR)

(21) Appl. No.: 18/847,611

(22) PCT Filed: Mar. 16, 2023
(86) PCT No.: PCT/EP2023/056740

§ 371 Date: Sep. 16, 2024

(30) Foreign Application Priority Data
Mar. 16, 2022 (FR) FR2202320

(51) Int. Cl. G06N 10/40; G06N 10/20; H10D 48/00

(52) U.S. Cl. CPC G06N 10/40; G06N 10/20; H10D 48/3835

(57) ABSTRACT

The invention relates to a method for calibrating a two-level spin quantum system coupled to a microwave cavity by a symmetric magnetic field and an antisymmetric magnetic field in the form of a double quantum dot comprising a left dot and a right dot, which system is subjected to a bias voltage, the method being characterized by the following steps: —setting the bias voltage (ε) to zero volts; —determining a wave function φp of each of the quantum dots; —calculating and/or setting the antisymmetric das and symmetric as magnetic coupling constants, calculating and/or setting the tunnel coupling constant, and/or the symmetric magnetic coupling constant αs and/or the antisymmetric magnetic coupling constant αas.

### CROSS-REFERENCE TO RELATED APPLICATIONS

This application is a national phase entry under 35 U.S.C. § 371 of International Patent Application PCT/EP2023/056740, filed Mar. 16, 2023, designating the United States of America and published as International Patent Publication WO 2023/175071 A1 on Sep. 21, 2023, which claims the benefit under Article 8 of the Patent Cooperation Treaty of French Patent Application Serial No. FR2202320, filed Mar. 16, 2022.

### TECHNICAL FIELD

The present disclosure relates to a method for assisting in the design of and/or a method for calibrating a qubit in order to perform quantum computing, using quantum components.

The quantum component is intended, in particular, but not exclusively, to manufacture a quantum computer.

### BACKGROUND

Semiconductor-hosted qubits have recently attracted a great deal of interest in the development of large-scale quantum computers.

This is because they have demonstrated good coherence times and quantum gate fidelity, enabled, in particular, by coupling via a microwave resonator, which is higher than purely magnetic coupling.

A spin quantum bit, also known as a spin qubit, is represented by an electron, whose spin, an eigenvector of a two-dimensional space, encodes the quantum information.

In all quantum systems, including spin qubits, quantum decoherence occurs when the quantum bit interacts with its external environment.

In order to model the quantum bit, two quantum dots are considered to correspond to the trapping of a single electron in two dots/wells, and thus the generating of a quantum bit.

From the paper M. Benito, J. R. Petta, and G. Burkard, Physical Review B 100 081412 (2019), “Optimized cavity-mediated dispersive two-qubit gates between spin qubits,” an interface between a single electron in a silicon dot/quantum dot and a single photon trapped in a superconducting cavity are known. This interface enables the implementation of photon-mediated two-qubit entanglement gates. In order to couple a spin to the cavity electric field, some type of spin-charge hybridization is required, which has an impact on spin control and coherence. A two-qubit cavity-mediated gate is proposed, and the fidelities of the cavity-mediated entanglement gate in the dispersive regime are calculated, taking into account errors due to spin-charge hybridization, as well as photon- and phonon-induced decays. It is planned to optimize the degree of spin-charge hybridization, with a view to proposing two-qubit gates mediated by cavity photons capable of achieving fidelities in excess of 90% in current device architectures. High fidelities for iSWAP gates are achievable even in the presence of charge noise at the 2μe V level.

Also known from the document A. Cottet and T. Kontos, Physical Review Letters 105:160502,2010 “A spin quantum bit with ferromagnetic contacts for circuit QED” is a scheme for a spin quantum bit based on a double quantum dot contacted to ferromagnetic elements. Interface exchange effects enable all-electric manipulation of the spin and a strong switchable coupling to a superconducting coplanar waveguide cavity, with a view to on-chip single spin manipulation and read-out using cavity QED techniques.

There are several problems that come with the prior art:

1. There are no well-defined adjustable parameters that allow the experimental physicist to control the operating regime of the spin-photon qubit. For example, in the Cottet and Kontos disclosure, the inhomogeneous magnetic field that forms a field gradient is highly specific and not linked to any adjustable parameter.

2. Because of the above problem, there is no systematic way to define a good operating regime, i.e., to design a qubit resistant to charge noise, the highest source of noise responsible for qubit decoherence.

3. There's no way to strike a good compromise between resistance to charge noise, while having good coupling to the cavity, which allows for better qubit control and therefore shorter gate time.

A gate is a quantum gate, corresponding to a logical operation that can change the state of superposition of a qubit. For example, a qubit can have a one-in-two chance of being in one or the other of the two states.

One aim of the present disclosure is to provide a method for assisting in the design and/or optimal calibration of a physical system containing a qubit spin photon with limited quantum decoherence, limited gate time and improved gate fidelity or reliability.

### BRIEF SUMMARY

To this end, and according to a first aspect, the present disclosure proposes a method for calibrating, or for assisting in the design of, a two-level spin quantum system or spin qubit, coupled to a microwave cavity by a symmetric magnetic field and an antisymmetric magnetic field, this quantum system being in the form of a double quantum dot comprising a left dot and a right dot, and being subjected to a bias voltage, characterized by the following steps:
setting the bias voltage (ε) to zero volts,
determining a wave function φp of each of the quantum dots,
calculating and/or setting the antisymmetric αas and symmetric αs magnetic coupling constants via the following formula: αi=2∫μBi(x)φp(x)*φp(x)dx, where φp is the electronic orbital wave function p (p=left dot or right dot), and Bi(x) is the symmetric Bs(x) and antisymmetric Bas(x) magnetic field,
calculating and/or setting the tunnel coupling constant (γ), and/or the symmetric magnetic coupling constant αs and/or the antisymmetric magnetic coupling constant αas such that:

$$2 γα s = α {s}^{2} + α {as}^{2}$$

$$and / or$$

$$P = \frac{{Ω}_{r}^{2}}{{Δε}_{r}^{2} + {Ω}_{r}^{2}}$$

is the desired probability of undesired transitions after applying the AC electric current
where

$${Ω}_{r} = {Ω}_{d} cos [ \frac{1}{2} ( arctan ( \frac{{α}_{as}}{2 γ + {α}_{s}} ) + arctan ( \frac{{α}_{as}}{2 γ - {α}_{s}} ) ) ]$$

$$and$$

$${Δε}_{τ} = 2 \sqrt{{( 2 γ - {α}_{s} )}^{2} + {α}_{as}^{2}} .$$

Ω_{d} is the qubit control amplitude.
Ωᵣ is the portion of the qubit's control amplitude associated with the qubit's orbital transition (known to the skilled person).
Δ_{εr} is the difference between the qubit orbital transition frequency and the frequency of the qubit control signal, the one sent with qubit control amplitude.

The spin and photon parts of a spin-photon qubit can be coupled in two ways: 1. by applying a symmetric and an antisymmetric magnetic field, and 2. by using a microwave cavity.

The present disclosure solves the above-mentioned problems by proposing a design for a good qubit operating regime, which results in a series of steps enabling an experimental physicist to gain access to a low-noise, highly controllable spin-photon qubit.

For the purposes of the foregoing and the rest of the description, calibration means preparing or setting the qubit to an optimum operating state.

Furthermore, for the purposes of this description, symmetric magnetic field means a magnetic field that is symmetric between two quantum dots, or a symmetric field between two quantum dots means a magnetic field of the same orientation, value and direction.

Furthermore, for the purposes of this description, antisymmetric magnetic field means a magnetic field that is antisymmetric between two quantum dots, or an antisymmetric field between two quantum dots means a magnetic field of the same orientation, same value and opposite direction.

In addition, the following expressions are used interchangeably: wave function or electronic orbital and will be represented interchangeably by the mathematical signs phi ϕ or psi ψ.

Similarly, the following expressions are used interchangeably: antisymmetric magnetic coupling or asymmetric magnetic coupling.

In addition, the following expressions are used interchangeably: double dot and double quantum dot.

In one embodiment, the wave functions are determined by solving a Schrödinger equation, preferably a single one, on the assumption that the system is a double-well electrostatic potential.

Preferably, for each wave function, the method comprises the following steps:
solving a Schrödinger equation on the assumption that the system is a double-well electrostatic potential,
calculating the wave functions in the absence of a magnetic field,
calculating the tunnel coupling constant γ,
applying symmetric Bs(x) and antisymmetric Bas(x) magnetic fields to the electron,
calculating the asymmetric αas and symmetric αs magnetic coupling constants.

Preferably, the symmetric magnetic field and/or the antisymmetric magnetic field is/are adjustable.

For example, the symmetric Bs(x) and antisymmetric Bas(x) magnetic fields are produced by magnets.

For example, the symmetric magnetic field Bs(x) is produced by a solenoid and the antisymmetric magnetic field Bas(x) is produced by at least one magnetically polarizing electrode, preferably at least one grid electrode.

Preferably, the bias voltage is adjustable, for example, via electrostatic potentials, preferably via gate electrodes of a quantum component.

According to a second aspect, the present disclosure provides for a quantum component comprising a two-level spin quantum system or spin qubit, coupled to a microwave cavity by a symmetric magnetic field and an antisymmetric magnetic field, this quantum system being in the form of a double quantum dot comprising a left dot and a right dot, the component comprising:
means for applying an electrostatic potential so as to apply a bias voltage (ε) to the double quantum dot,
means for applying a symmetric magnetic field and an antisymmetric magnetic field between the left and right dots, respectively,
characterized in that it further comprises a bias voltage (ε) maintained at zero volts and a tunnel coupling constant and/or the symmetric magnetic coupling constant αs and/or the antisymmetric magnetic coupling constant αas such that:

$$2 γα s = α {s}^{2} + α {as}^{2}$$

$$and / or$$

$$P = \frac{{Ω}_{r}^{2}}{{Δε}_{r}^{2} + {Ω}_{r}^{2}}$$

is the desired probability of undesired transitions after applying the AC electric current
where

$${Ω}_{r} = {Ω}_{d} cos [ \frac{1}{2} ( arctan ( \frac{{α}_{as}}{2 γ + {α}_{s}} ) + arctan ( \frac{{α}_{as}}{2 γ - {α}_{s}} ) ) ]$$

$$and$$

$${Δε}_{τ} = 2 \sqrt{{( 2 γ - {α}_{s} )}^{2} + {α}_{as}^{2}} ,$$

where αs and αas are respectively symmetric and asymmetric magnetic coupling constants via the following formula:

$$α i = 2 \int μ Bi ( x ) φ p ( x ) * φ p ( x ) dx ,$$

where φp is the wave function of the electronic orbital p (p=left dot or right dot), and Bi(x) is the symmetric magnetic field Bs(x) and the antisymmetric magnetic field Bas(x).

Preferably, the quantum component comprises one or more of the features of the first aspect.

There are several ways of constructing a qubit.

The key factor that differentiates a good qubit from a bad one is its susceptibility to decoherence.

This affects not only the qubit lifetime and therefore the maximum depth of a quantum circuit running on the processor, but also the error rates of individual quantum gates.

So, in order to identify whether carbon nanotubes are good hosts for the construction of a quantum information device, it is crucial to identify the processes leading to qubit decoherence.

In order to have a somewhat realistic description of the qubit and the quantum operations to be performed, deviations need to be taken into account that accompany the qubit's external environment, such as charge noise.

However, this is not the only source of qubit decoherence.

They are separated into two categories according to their effect on the qubit.

Relaxation refers to the processes by which the qubit relaxes toward its ground state over time, while phase shifting refers to the processes by which the two qubit states acquire a different phase over time.

### BRIEF DESCRIPTION OF THE DRAWINGS

Other features and advantages of the present disclosure will emerge from the following detailed description of the present disclosure with reference to the appended figures, and in which:

FIG. 1 shows a diagram of a double quantum dot in one mode of representation;

FIG. 2 shows a schematic diagram of a quantum component comprising a nanotube arranged above electrodes, in particular, non-collinear magnetic electrodes;

FIG. 3 shows a schematic diagram of a quantum component comprising a nanotube arranged above electrodes, displaying a dipolar leakage magnetic field;

FIG. 4 shows two graphs one above the other, the top graph showing, on the one hand, in a solid gray line, the electrostatic potential in a nanotube as a function of the distance in nanometers, and on the other hand via the black lines, the two binding (black solid line) and antibinding (black dotted line) states of an electron in a double quantum dot, and the bottom graph showing the profile of two magnetic flux leakage components.

FIG. 5 shows a graph representing four qubit energy levels and illustrating the reduction of charge noise; and

FIG. 6 shows curves of magnetic field components along a carbon nanotube, in particular, the magnetic field distribution along a carbon nanotube obtained with micro-magnets.

For greater clarity, identical or similar elements of the various embodiments are denoted by identical reference signs in all of the figures.

### DETAILED DESCRIPTION

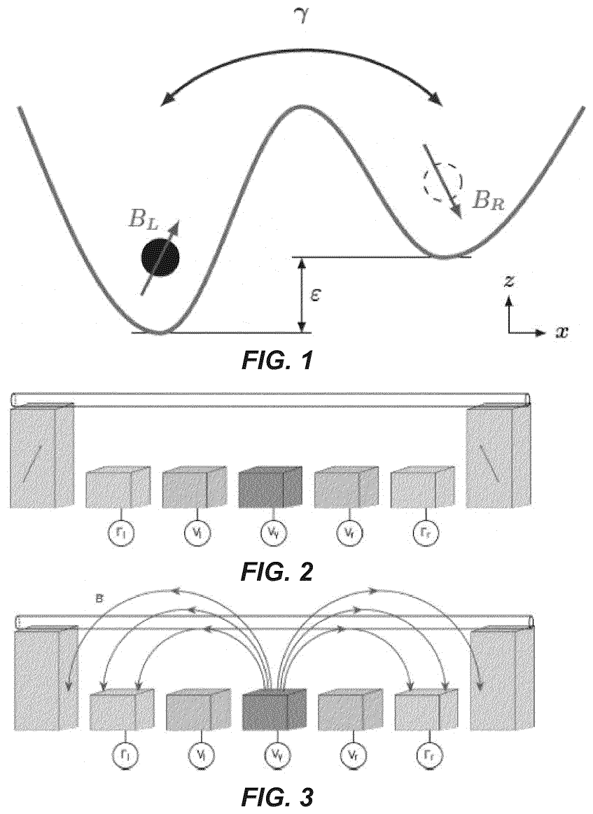

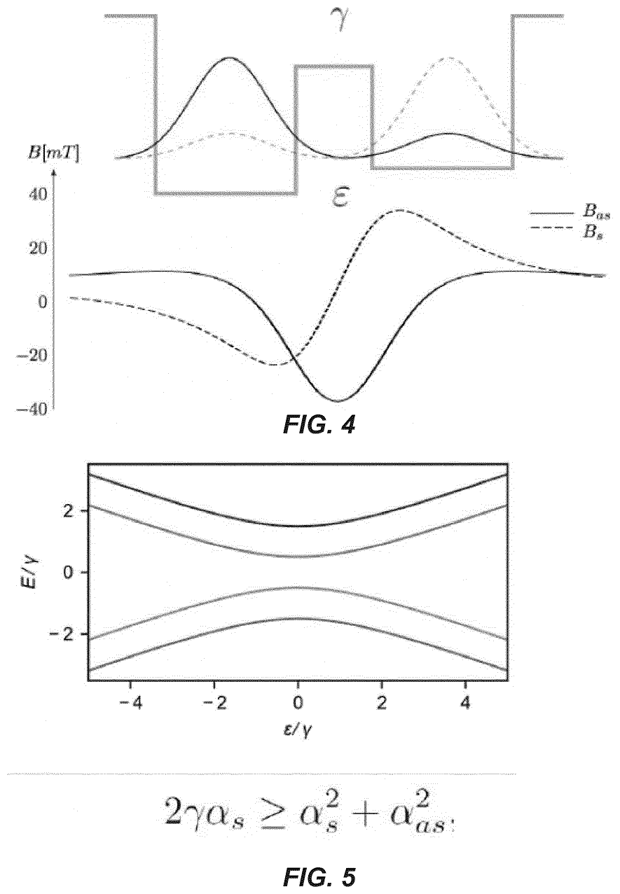

In connection with FIG. 1, in one embodiment, steps of the method are described for calibrating, or assisting in the design of, a two-level spin quantum system or spin qubit, this quantum system being in the form of a double quantum dot.

FIGS. 1-3 illustrate the charge-controlled spin state. In particular, FIG. 1 illustrates an electron spin S=½ in a double quantum dot in a homogeneous magnetic field. FIG. 2 illustrates the presence of an inhomogeneous magnetic field represented by the diagonal arrows on the suspension electrodes, known as source and drain electrodes. FIG. 3 illustrates the presence of an inhomogeneous magnetic field, represented by the arced arrows, generated by a magnetic electrode forming a magnet or magnetic dipole, and producing a leakage field outside the magnetic electrode.

### Defining Adjustable Variables for Simulation and Design:

For a physical system that hosts a spin qubit in a double quantum dot (DQD), coupled to a magnetic field with a symmetric and an antisymmetric component, it is possible to model the physical behavior of the system with the following Hamiltonian:

$$H = \frac{ε}{2} τ \text{?} + γ τ \text{?} + \frac{α \text{?}}{2} σ \text{?} τ \text{?} + \frac{α \text{?}}{2} σ \text{?}$$

$$\text{?} \text{indicates text missing or illegible when filed}$$

where τi are the Pauli operators of the electronic orbitals in the double dot (left dot and right dot),

$$τ \text{?} = \vert {ψ}_{L} 〉 〈 {ψ}_{L} \vert - \vert {ψ}_{R} 〉 〈 {ψ}_{R} \vert$$

$${τ}_{x} = \vert {ψ}_{L} 〉 〈 {ψ}_{R} \vert - \vert {ψ}_{R} 〉 〈 {ψ}_{L} \vert$$

$$\text{?} \text{indicates text missing or illegible when filed}$$

σi are the Pauli operators of the electron spin in the double quantum dot. The four parameters with which it is possible to adjust the qubit spin are:
ε is the polarization voltage applied to the double quantum dot, it is easily tuned experimentally;
γ is the tunnel coupling constant between the two dots;
αs is the coupling parameter between the symmetric part of the applied magnetic field and the electron's magnetic moment;
αas is the coupling parameter between the asymmetric part of the applied magnetic field and the electron's magnetic moment.

### Calculating and Setting the Four Spin Qubit Variables

Physically, it is possible to manipulate these four variables by controlling either:
the magnetic field applied to the DQD: (Bs(x), Bas(x)), x being the direction along the DQD.

This representation allows the applied magnetic field to couple the electron's spin to its location on the spin qubit.

For example, it is possible to control the magnetic field intensity in both directions in real time by adjusting the current flowing through a solenoid, which is the physical embodiment of the magnet.

The magnetic field can be adjusted.
the applied electrostatic potential V(x), which depends on the design of the physical system hosting the double quantum dot (DQD), and, for example, on the voltages applied to the electrodes controlling the qubit.

One way of arriving at V(x) would then be to use a numerical method such as the finite element method to solve Maxwell's equations.

The electrostatic potential V(x) can be set. Several embodiments exist for carrying out this setting.

According to one embodiment, the Schrödinger equation of the electron in the DQD is solved, with a fixed electrostatic potential V(x) and bias voltage ε=0.

$$( - \frac{{h}^{2}}{2 m} {∇}_{x}^{2} + V ( x ) ) ψ ( x ) = E ψ ( x )$$

This equation can be solved numerically, for example, using the finite element method.

The solution to this equation is an infinite-dimensional vector space.

Only the vector subspace associated with the first two eigenvalues of the Hamiltonian are kept, which are called (E+,E−) with their respective associated wave functions (ψ+(x), ψ−(x)).

The tunnel coupling constant γ can be calculated numerically with the following equation, where the bias voltage is zero, based on the previously calculated eigenvalue:

$$γ = {E}_{+} ( ε = 0 )$$

Next, the left and right eigenstates ψL(x) and ψR(x) can be calculated on the basis of the numerical values of the previously calculated wave functions ψ+(x) and ψ−(x):

$${ψ}_{L} ( x ) = \frac{1}{\sqrt{2}} ( {ψ}_{+} ( x ) + {ψ}_{-} ( x ) )$$

$${ψ}_{R} ( x ) = \frac{1}{\sqrt{2}} ( {ψ}_{+} ( x ) - {ψ}_{-} ( x ) )$$

Next, the magnetic coupling constants are numerically calculated by computing the following integrals, which can be done numerically:

$${α}_{s} = 2 \int {μ}_{B} {B}_{s} ( x ) {ψ}_{L}^{*} ( x ) {ψ}_{L} ( x ) dx$$

$${α}_{as} = 2 \int {μ}_{B} {B}_{as} ( x ) {ψ}_{L}^{*} ( x ) {ψ}_{L} ( x ) dx$$

### Optimum Qubit Working Point:

On the basis of the adjustable parameters defined above, it is possible to define the qubit's optimal operating regime by ensuring that certain equations are satisfied by the adjustable parameters:

### Maximum Spin-Photon Coupling:

The regime at which spin-photon coupling is maximal, allowing the quantum gate time to be as short as possible, can be set by adjusting the bias voltage as ε=0.

This places the qubit in a perfectly symmetric regime between the two dots and maximizes the coupling between the photonic cavity, the charge aspect of the qubit and the spin aspect of the qubit. This maximizes spin-photon coupling.

### Trade-Off Between Low Charge Noise and Spin-Photon Coupling:

Once the previous step has been completed, the qubit regime can be adjusted to achieve a good compromise between low charge noise and good spin-photon coupling. This can be achieved by defining the three remaining spin qubit parameters as:

$$2 γ {α}_{s} = {α}_{s}^{2} + {α}_{as}^{2}$$

This adjustment can be made by varying the magnetic field (Bas(x), Bs(x)) and the electrostatic potential V(x).

For example, the magnetic field may be fixed for experimental reasons, and several values of electrostatic potential may be calculated numerically until the above equation is satisfied.

This provides a good compromise between low charge noise and good spin-photon coupling.

### Low-Error Qubit Gate:

When AC electrical control is applied to the qubit (e.g., a microwave signal) to apply a 1-qubit gate (e.g., an X-gate) to the spin-photon qubit, this induces errors leading to unwanted transitions.

The qubit can reach a third state, resulting in loss of information and errors in calculations using 1-qubit gates. It is possible to set a given electrical control amplitude Ωd as desired on the basis of experimental considerations, for example, with the amplitude of the microwave signal sent to the device.

Errors can then be minimized by adjusting well-defined qubit parameters so that a certain equation is satisfied.

Temporary variables can be introduced to simplify mathematical expressions:

$${Ω}_{τ} = {Ω}_{d} cos [ \frac{1}{2} ( arctan ( \frac{{α}_{as}}{2 γ + {α}_{s}} ) + arctan ( \frac{{α}_{as}}{2 γ + {α}_{s}} ) ) ]$$

$$Δ {ε}_{τ} = 2 \sqrt{{( 2 γ - {α}_{s} )}^{2} + {α}_{as}^{2}}$$

which depend only on the three adjustable qubit parameters as, αas and γ, as well as the adjustable control amplitude applied to the qubit Ωd.

So that a certain probability of reaching an undesirable transition after the application of the electric drive is very low, for example, P=0.01%, the following quantity can be calculated:

$$P = \frac{{Ω}_{τ}^{2}}{Δ {ε}_{τ}^{2} + {Ω}_{τ}^{2}}$$

P is the desired probability of undesired transitions after the AC electric current has been applied (e.g., after an X gate has been applied).

It is possible to adjust the qubit parameters so that P=0.01%, corresponding to very good operation of a single-qubit quantum gate.

The set of steps uses the previously defined adjustable parameters, which are directly related to the experimental parameters of the magnetic field and electrostatic potentials, after which the qubit finds itself in the optimal operating regime.

This happens because these adjustable parameters satisfy the following set of equations:

$$ε = 0$$

$$2 γ {α}_{s} = {α}_{s}^{2} + {α}_{as}^{2}$$

$$P = \frac{{Ω}_{τ}^{2}}{Δ {ε}_{τ}^{2} + {Ω}_{τ}^{2}}$$

FIG. 5 illustrates the qubit operating regime that satisfies the presented inequality and results in the qubit frequency, i.e., the difference between the energy levels of the second curve from the bottom of the graph and the first curve from the bottom of the graph, being a constant function of the qubit's epsilon bias voltage. As it is the variation of this function that quantifies the charge noise, such a regime protects the qubit from this charge noise.

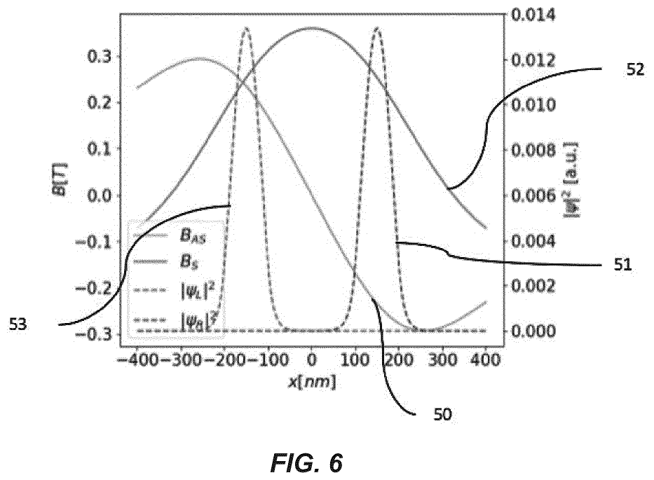

In a particular embodiment, the distribution components of the magnetic field along a carbon nanotube are illustrated in FIG. 6. The symmetric component is referenced by 52. The antisymmetric component is referenced by 50. The wave functions are referenced by 51 and 53. For example, magnetic field 52 is symmetric with respect to the x=0 plane, the x-axis of FIG. 6. For example, magnetic field 50 is antisymmetric with respect to the x=0 plane, the x-axis of FIG. 6.

1. A method for calibrating a two-level spin quantum system or spin qubit, coupled to a microwave cavity by a symmetric magnetic field and an antisymmetric magnetic field, the quantum system being in the form of a double quantum dot comprising a left dot and a right dot, and being subjected to a bias voltage, the method comprising:
setting the bias voltage (ε) to zero volts;
determining a wave function φp of each of the quantum dots;
calculating and/or setting the antisymmetric αas and symmetric αs magnetic coupling constants using the following formula:
$$α i = 2 \int μ Bi ( x ) φ p ( x ) * φ p ( x ) dx ,$$
where φp is the wave function of the electronic orbital p, p corresponding to the left dot or the right dot, and Bi(x) is the symmetric magnetic field Bs(x) and the antisymmetric magnetic field Bas(x); and
calculating and/or setting the tunnel coupling constant (γ), and/or the symmetric magnetic coupling constant αs and/or the antisymmetric magnetic coupling constant αas such that:
$$2 γ {α}_{s} = {α}_{s}^{2} + {α}_{as}^{2}$$
$$and / or$$
$$P = \frac{{Ω}_{τ}^{2}}{Δ {ε}_{τ}^{2} + {Ω}_{τ}^{2}}$$
is the desired probability of undesired transitions after applying the AC electric current,
where
$${Ω}_{τ} = {Ω}_{d} cos [ \frac{1}{2} ( arctan ( \frac{{α}_{as}}{2 γ + {α}_{s}} ) + arctan ( \frac{{α}_{as}}{2 γ + {α}_{s}} ) ) ]$$
$$and$$
$$Δ {ε}_{τ} = 2 \sqrt{{( 2 γ - {α}_{s} )}^{2} + {α}_{as}^{2}} .$$

2. The method of claim 1, wherein the wave functions are determined by solving a Schrödinger equation on the assumption that the system is a double-well electrostatic potential.

3. The method of claim 2, wherein the symmetric magnetic field and/or the antisymmetric magnetic field is/are adjustable.

4. The method of claim 2, further comprising:
calculating each wave functions in the absence of a magnetic field;
calculating the tunnel coupling constant (γ);
applying symmetric Bs(x) and antisymmetric Bas(x) magnetic fields to the electron; and
calculating the asymmetric αas and symmetric αs magnetic coupling constants.

5. The method of claim 1, wherein the symmetric Bs(x) and antisymmetric Bas(x) magnetic fields are realized by magnets.

6. The method of claim 1, wherein the symmetric magnetic field Bs(x) is realized by a solenoid and the antisymmetric magnetic field Bas(x) is realized by at least one magnetically polarizing electrode.

7. The method of claim 1, wherein the bias voltage is adjustable.

8. A quantum component comprising a two-level spin quantum system or spin qubit, coupled to a microwave cavity by a symmetric magnetic field and an antisymmetric magnetic field, this quantum system being in the form of a double quantum dot comprising a left dot and a right dot, the component comprising:
means for applying an electrostatic potential so as to apply a bias voltage (ε) to the double quantum dot;
means for applying a symmetric magnetic field and an antisymmetric magnetic field between the left and right dots, respectively;
wherein a bias voltage (ε) is maintained at zero volts and a tunnel coupling constant (γ) and/or the symmetric magnetic coupling constant αs and/or the antisymmetric magnetic coupling constant αs such that:
$$2 γ {α}_{s} = {α}_{s}^{2} + {α}_{as}^{2}$$
$$and / or$$
$$P = \frac{{Ω}_{τ}^{2}}{Δ {ε}_{τ}^{2} + {Ω}_{τ}^{2}}$$
is the desired probability of undesired transitions after applying the AC electric current,
where
$${Ω}_{τ} = {Ω}_{d} cos [ \frac{1}{2} ( arctan ( \frac{{α}_{as}}{2 γ + {α}_{s}} ) + arctan ( \frac{{α}_{as}}{2 γ + {α}_{s}} ) ) ]$$
$$and$$
$$Δ {ε}_{τ} = 2 \sqrt{{( 2 γ - {α}_{s} )}^{2} + {α}_{as}^{2}}$$
where αas and αs are respectively symmetric and asymmetric magnetic coupling constants via the following formula: αi=2∫μBi(x)φₚ(x)*φₚ(x)dx, where φp is the electronic orbital wave function p (p=left dot or right dot), and Bi(x) is the symmetric Bs(x) and antisymmetric Bas(x) magnetic field.

9. The method of claim 1, wherein the symmetric magnetic field and/or the antisymmetric magnetic field is/are adjustable.

10. The method of claim 1, further comprising:
calculating each wave functions in the absence of a magnetic field;
calculating the tunnel coupling constant (γ);
applying symmetric Bs(x) and antisymmetric Bas(x) magnetic fields to the electron; and
calculating the asymmetric αas and symmetric αs magnetic coupling constants.

11. The method of claim 6, wherein the at least one magnetically polarizing electrode comprises at least one grid electrode.
